(19) United States
(12) Patent Application Publication
(10) Pub. No.: US 2007/0252172 A1
(43) Pub. Date: Nov. 1, 2007

(54) SEMICONDUCTOR DEVICE

(75) Inventors: Tetsuya Hayashi, Yokosuka-shi (JP); Masakatsu Hoshi, Yokohama-shi (JP); Yoshio Shimoida, Yokosuka-shi (JP); Hideaki Tanaka, Yokohama-shi (JP); Shigeharu Yamagami, Yokohama-shi (JP)

Correspondence Address: FOLEY AND LARDNER LLP;SUITE 500, 3000 K STREET NW, WASHINGTON, DC, 20007, US

(73) Assignee: NISSAN MOTOR CO., LTD.

(21) Appl. No.: 11/741,305

(22) Filed: Apr. 27, 2007

(30) Foreign Application Priority Data
Apr. 28, 2006 (JP) 2006-125399

(51) Int. Cl. H01L 31/00

(52) U.S. Cl. 257/192

(57) ABSTRACT

A semiconductor device, includes: 1) a semiconductor base having a first face; 2) a hetero semiconductor region configured to contact the first face of the semiconductor base and different from the semiconductor base in band gap, the semiconductor base and the hetero semiconductor region defining therebetween a junction part in the hetero semiconductor region, a concentration of an impurity introduced in at least a first certain region including the junction part being less than or equal to a solid solution limit to a semiconductor material included in the hetero semiconductor region; 3) a gate electrode formed, via a gate insulation film, in a certain position adjacent to the junction part; 4) a source electrode configured to be connected to the hetero semiconductor region; and 5) a drain electrode configured to be connected to the semiconductor base.

### BACKGROUND OF THE INVENTION

1. Field of the Invention

The present invention relates to a semiconductor device, especially, to a technology for decreasing on resistance of a hetero junction transistor or a hetero junction diode.

2. Description of the Related Art

Japanese Patent Application Laid-Open No. 2003-318398 (=JP2003318398) applied for by the present applicant discloses a silicon carbide semiconductor device.

According to the conventional technology in JP2003318398, an N⁻ type polycrystalline silicon region 60 is so formed as to contact a first main face of a semiconductor base including an N⁻ type silicon carbide epitaxial region 20 on an N⁺ type silicon carbide substrate region 10. The N⁻ type silicon carbide epitaxial region 20 and the N⁻ type polycrystalline silicon region 60 in combination form a hetero junction, thereby the N⁻ type polycrystalline silicon region 60 can operate as a hetero semiconductor region. Moreover, adjacent to the hetero junction part between the N⁻ type silicon carbide epitaxial region 20 and the N⁻ type polycrystalline silicon region 60, there is formed a gate electrode via a gate insulating film 30. The N⁻ type polycrystalline silicon region 60 is connected to a source electrode 80, while the N⁺ type silicon carbide substrate region 10 has a back face formed with a drain electrode 90.

The semiconductor device having the above structure according to the conventional technology serves as a switch when a potential of the gate electrode 90 is controlled in a state where the source electrode 80 is grounded and a certain positive potential is applied to the drain electrode 90. That is, with the gate electrode grounded, a reverse bias is applied to the hetero junction between the N⁻ type polycrystalline silicon region 60 and the N⁻ type silicon carbide epitaxial region 20, leaving no current flowing between the drain electrode 90 and the source electrode 80. Contrary to the above, with a certain positive voltage applied to the gate electrode, a gate electric field is caused to the hetero junction part (interface) between the N⁻ type polycrystalline silicon region 60 and the N⁻ type silicon carbide epitaxial region 20, thereby decreasing thickness of an energy barrier formed by the hetero junction part of a gate oxidized film interface, thus flowing the current between the drain electrode 90 and the source electrode 80.

### SUMMARY OF THE INVENTION

It is an object of the present invention to provide a semiconductor device capable of decreasing on resistance during conduction.

According to a first aspect of the present invention, there is provided a semiconductor device, comprising: 1) a semiconductor base having a first face; 2) a hetero semiconductor region configured to contact the first face of the semiconductor base and different from the semiconductor base in band gap, the semiconductor base and the hetero semiconductor region defining therebetween a junction part in the hetero semiconductor region, a concentration of an impurity introduced in at least a first certain region including the junction part being less than or equal to a solid solution limit to a semiconductor material included in the hetero semiconductor region; 3) a first electrode configured to be connected to the hetero semiconductor region; and 4) a second electrode configured to be connected to the semiconductor base.

According to a second aspect of the present invention, there is provided a semiconductor device, comprising: 1) a semiconductor base having a first face; 2) a hetero semiconductor region configured to contact the first face of the semiconductor base and different from the semiconductor base in band gap, the semiconductor base and the hetero semiconductor region defining therebetween a junction part in the hetero semiconductor region, a concentration of an impurity introduced in at least a first certain region including the junction part being less than or equal to a solid solution limit to a semiconductor material included in the hetero semiconductor region; 3) a gate electrode formed, via a gate insulation film, in a certain position adjacent to the junction part; 4) a source electrode configured to be connected to the hetero semiconductor region; and 5) a drain electrode configured to be connected to the semiconductor base.

The other object(s) and feature(s) of the present invention will become understood from the following description with reference to the accompanying drawings.

### BRIEF DESCRIPTION OF THE DRAWINGS

FIG. 1 is a cross sectional view showing a semiconductor device, according to a first embodiment of the present invention.

FIG. 2 is a graph showing an example of distribution of impurity concentration in and adjacent to a hetero junction part between a hetero semiconductor region and a drift region of the semiconductor device.

FIG. 3 is a cross sectional view of a semiconductor device which is a diode different from the semiconductor device which is a transistor in FIG. 1, according to the first embodiment of the present invention.

FIG. 4 is a graph showing forward current-voltage characteristics observed when a forward bias is applied to the diode of the semiconductor device in FIG. 3.

FIG. 5 is a graph showing a forward current, relative to the impurity concentration observed in and adjacent to the hetero junction part of the diode of the semiconductor device in FIG. 3.

FIG. 6 is a graph showing electrical indexes, relative to the impurity concentration observed in and adjacent to the hetero junction part of the diode of the semiconductor device in FIG. 3.

FIG. 7 is a graph showing characteristic distribution of on resistance concerning the transistor of the semiconductor device in FIG. 1, with an introduced impurity concentration as a parameter.

FIG. 8 is a cross sectional view of a semiconductor device, according to a second embodiment of the present invention.

FIG. 9 is a cross sectional view of a semiconductor device, according to a third embodiment of the present invention.

FIG. 10 is a cross sectional view of a semiconductor device, according to a fourth embodiment of the present invention.

FIG. 11 is a cross sectional view of a semiconductor device, according to a fifth embodiment of the present invention.

FIG. 12 is a cross sectional view of a semiconductor device, according to sixth embodiment of the present invention.

FIG. 13 is a cross sectional view of a semiconductor device, according to the seventh embodiment of the present invention.

### DESCRIPTION OF THE PREFERRED EMBODIMENTS

In the following, various embodiments of the present invention will be described in detail with reference to the accompanying drawings.

For ease of understanding, the following description will contain various directional terms, such as left, right, upper, lower, forward, rearward and the like. However, such terms are to be understood with respect to only a drawing or drawings on which the corresponding part of element is illustrated.

Hereinafter, semiconductor devices are to be set forth in detail referring to drawings, according to preferred embodiments of the present invention.

### First Embodiment

### (Structure)

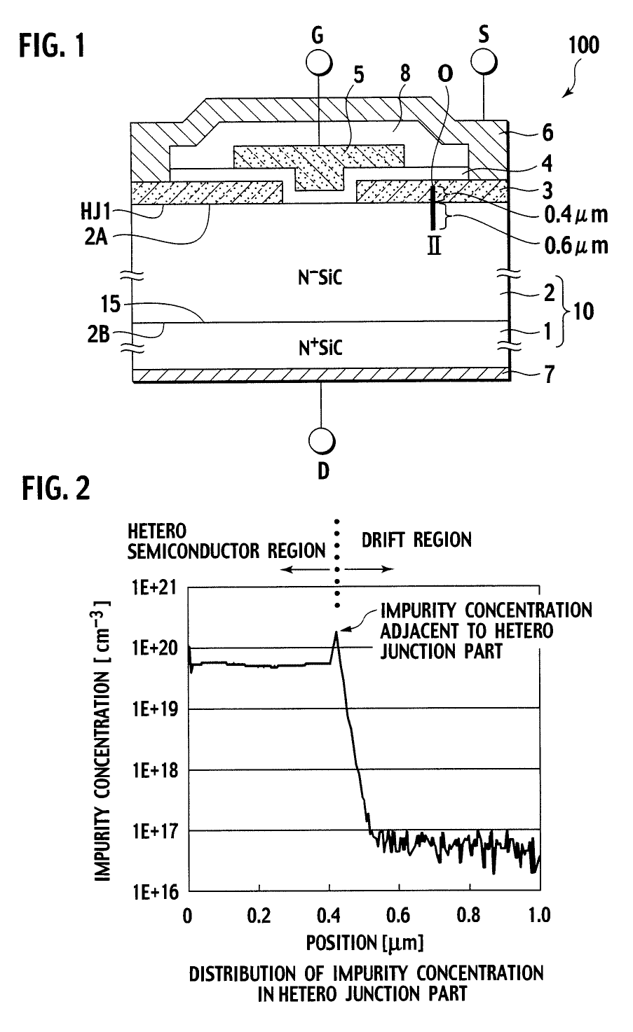

FIG. 1 is a cross sectional view of a semiconductor device 100, according to a first embodiment of the present invention. The semiconductor device 100 in FIG. 1 includes a hetero junction transistor having two structural unit cells facing each other. Actually, however, these plural cells are connected in parallel, to thereby form an element. In addition, according to the first embodiment, the semiconductor device 100 has substrate material made of silicon carbide.

In the semiconductor device 100 in FIG. 1, for example, an N⁻ type drift region 2 made of silicon carbide is formed on an N⁺ type substrate region 1 made of silicon carbide having 4H poly type (4H: 4-layer hexagonal crystal), to thereby form a semiconductor base 10 having a semiconductor region on a substrate. Moreover, a hetero semiconductor region 3 is formed in a certain region in such a configuration as to contact a first main face 2A (of the drift region 2) opposing a second main face 2B having a junction face 15 with the substrate region 1. The hetero semiconductor region 3 is made of a semiconductor material (for example, N type polycrystalline silicon) different from the semiconductor base 10 in band gap. That is, a part between the drift region 2 and the hetero semiconductor region 3 forms a hetero junction made of the materials different in band gap, that is, the silicon carbide and the polycrystalline silicon. A hetero junction part HJ1 (otherwise referred to as “hetero junction” or “hetero junction interface”) includes an energy barrier. Hereinabove and hereinafter, the superscript “+” denotes that an introduced impurity has high concentration, while the superscript “−” denotes low concentration.

Moreover, a gate insulating film 4 made of, for example, silicon oxidized film is formed in such a configuration as to contact the hetero junction part HJ1 (patterned on a certain region) between the hetero semiconductor region 3 and the drift region 2. Moreover, a gate electrode 5 is formed on the gate insulating film 4, and a source electrode 6 is formed on a surface layer opposing the hetero junction part HJ1 between the drift region 2 and the hetero semiconductor region 3, in such a configuration as to cause an ohmic connection. Meanwhile, a drain electrode 7 is formed on the substrate region 1 in such a configuration as to cause an ohmic connection. An interlayer insulating film 8 is formed between the source electrode 6 and the gate electrode 5.

Herein, with the semiconductor device 100 according to the first embodiment in FIG. 1, impurity concentration in and adjacent to the hetero junction part HJ1 (interface) in the hetero semiconductor region 3 can be controlled, where the hetero junction part HJ1 (interface) contacts the drift region 2. The impurity concentration are to be set within a certain range (less than or equal to 1E21 cm³1×10²¹ cm⁻³, to be described afterward) in at least one of the following i) and ii):
i) a certain part of the hetero junction part HJ1 in the hetero semiconductor region 3, the certain part contacting the gate insulating film 4, and
ii) at least a first certain region in and adjacent to the hetero junction part HJ1 (interface).

FIG. 2 is a graph showing an example of distribution of the impurity concentration in and adjacent to the hetero junction part HJ1 between the hetero semiconductor region 3 and the drift region 2 of the semiconductor device 100, for example, a distribution of impurity concentration in a region denoted by a line segment II in the semiconductor device 100 in FIG. 1, the distribution being observed through an SIMS (Secondary Ionization Mass Spectrometer) analysis. In addition, actually, the region (serving as the hetero junction part HJ1 between the hetero semiconductor region 3 and the drift region 2) for controlling the impurity concentration introduced is preferred to include at least the certain part where the hetero junction part HJ1 contacts the gate insulating film 4. Therefore, an observation part denoted by the line segment II is measured in a certain position adjacent to the certain part.

The graph in FIG. 2 shows distribution of the impurity concentration to a position entering by 0.6 μm into the drift region 2 side over the hetero junction part HJ1 between the hetero semiconductor region 3 and the drift region 2, and based on a standard position O (original point) entering by 0.4 μm into the hetero semiconductor region 3 side from the hetero junction part HJ1. The impurity concentration has a peak in the hetero junction part HJ1. Meanwhile, the impurity concentration on the hetero semiconductor region 3 side is about 1E+20 cm⁻³=1×10²⁰ cm⁻³, much higher than about 1E+17 cm⁻³=1×10¹⁷ cm−³ on the drift region 2 side.

### (Operation)

Then, an example of an operation of the semiconductor device 100 in FIG. 1 is to be set forth. According to the first embodiment, for example, the source electrode 6 is grounded and a positive potential is applied to the drain electrode 7.

At first, for example, when the gate electrode 5 is grounded or has a negative potential, the semiconductor device 100 keeps a shutoff state. The reason therefor is that the hetero junction part HJ1 (interface) between the hetero semiconductor region 3 and the drift region 2 is formed with the thick energy barrier against conduction electron.

Then, when a positive potential is applied to the gate electrode 5 for converting the shutoff state to a conduction state, a gate electric field extends via the gate insulating film 4 to the hetero junction part HJ1 (interface) where the hetero semiconductor region 3 and the drift region 2 contact each other, to thereby form a storage layer of the conduction electron in surface layer parts of the hetero semiconductor region 3 and drift region 2 which are disposed adjacent to the gate electrode 5. As a result, the surface layer parts of the hetero semiconductor region 3 and drift region 2 each have a potential for allowing a free electron, making more precipitous the energy barrier extending to the drift region 2 side, to thereby make the energy barrier thinner. Therefore, the conduction electron, namely, the electron current is allowed to make a conduction by tunneling in the energy barrier.

Then, applying the ground potential again to the gate electrode 5 for converting the conduction state to the shutoff state will release the storage state of the conduction electron formed in the hetero junction part HJ1 (interface) between the hetero semiconductor region 3 and the drift region 2, to thereby stop the tunneling in the energy barrier. Then, the conduction electron flow from the hetero semiconductor region 3 to the drift region 2 will stop. Moreover, the conduction electron in the drift region 2 flows to the substrate region 1, to thereby cause a depletion. Then, a depletion layer expands on the drift region 2 side from the hetero junction part HJ1 between the drift region 2 and the hetero semiconductor region 3, thus bringing about the shutoff state.

Moreover, according to the first embodiment, like the conventional structure, a reverse conduction (reflux operation) is allowed, for example, with the source electrode 6 grounded and a negative potential applied to the drain electrode 7.

For example, applying a certain negative potential to the drain electrode 7 with both the source electrode 6 and the gate electrode 5 grounded eliminates the energy barrier against the conduction electron, thereby flowing the conduction electron from the drift region 2 side to the hetero semiconductor region 3 side, thus bringing about a reverse conduction state. In this case, without implantation of positive pore, the conduction is accomplished only by the conduction electron, thereby decreasing loss which may be caused by reverse recovery current for converting the reverse conduction state to the shutoff state. In addition, instead of being grounded, as described above, the gate electrode 5 can be used as a control electrode for applying a controlling voltage.

### (Experimental Example)

Then, the present inventors have found out the following through experiments:

With the structure of the semiconductor device 100 in FIG. 1, the scale of the impurity concentration in the hetero semiconductor region 3 in and adjacent to the hetero junction part HJ1 (the impurity concentration shown as an example in graph in FIG. 2) vary the on resistance during conduction. Experimental results thereof are to be set forth in detail hereinafter.

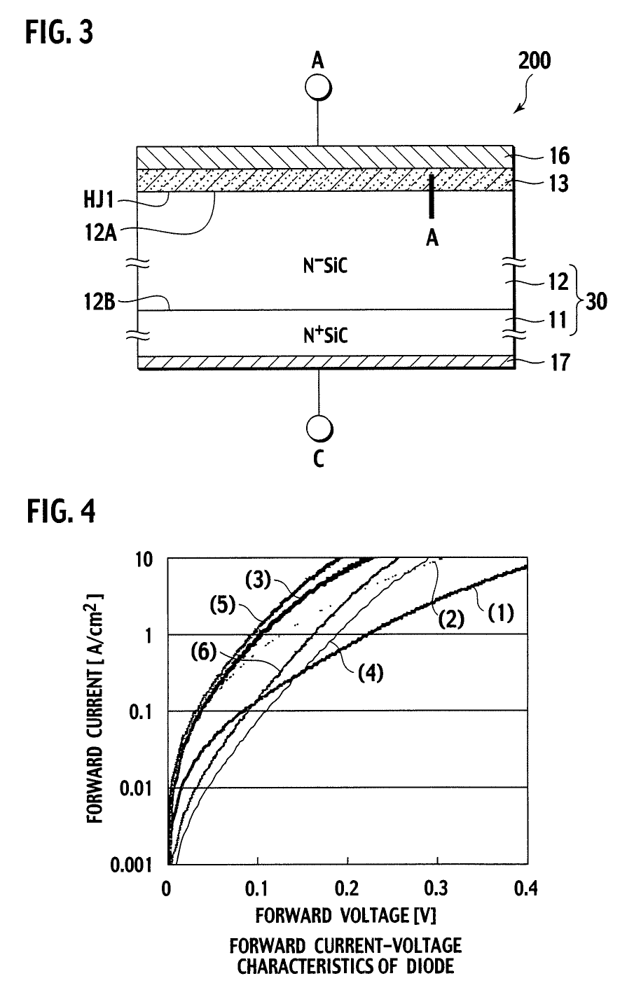

For studying the on resistance of the transistor of the semiconductor device 100, relative to the impurity concentration in the hetero junction part HJ1, the present inventors also prepared a hetero junction diode in FIG. 3 which diode is usable for electrically evaluating characteristics of the impurity concentration in and adjacent to the hetero junction part HJ1 (interface). Herein, FIG. 3 is a cross sectional view of a semiconductor device 200, according to the first embodiment. The semiconductor device 200 in FIG. 3 is different in cross section from the semiconductor device 100 in FIG. 1. In other words, FIG. 3 shows one structural example of the hetero junction diode.

The semiconductor device 200 Petero junction diode) in FIG. 3 is substantially similar in structure to the semiconductor device 100 (hetero junction transistor) in FIG. 1. Specifically, an N⁻ type drift region 12 made of silicon carbide is formed on an N⁺ type substrate region 11 made of silicon carbide as the semiconductor base 10, to thereby form a semiconductor base 30. On the N⁻ type drift region 12, there is formed a hetero semiconductor region 13 made of N type polycrystalline silicon which is a semiconductor material different in band gap from that of the semiconductor base 30. An anode 16 as a first electrode is formed on a surface layer of the hetero semiconductor region 13, while a cathode 17 as a second electrode is formed on the substrate region 11, in such a manner as to form an ohmic connection.

Set forth at first include structures of: i) the semiconductor device 100 in FIG. 1 namely, the hetero junction transistor, and ii) the semiconductor device 200 in FIG. 2, namely, the hetero junction diode, which two devices are used for the experiment As described above, the 4H type silicon carbide is used for the substrate material for each of the substrate region 1 and the substrate region 11. The drift region 2 and the drift region 12 each having a thickness about 10 μm, impurity concentration about 10¹⁶ cm⁻³ and being made of N⁻ type silicon carbide are formed respectively on the substrate region 1 and the substrate region 11 each being of N⁺ type and having low resistance, to thereby prepare the epitaxial substrates used for the semiconductor bases 10, 30.

On the drift region 2 and the drift region 12, there are formed respectively the hetero semiconductor region 3 and the hetero semiconductor region 13 each having thickness about 0.5 μm and made of N type polycrystalline silicon having impurity concentration selected from a plurality of impurity concentrations in a range from about 10¹⁸ cm⁻³ to about 10²² cm⁻³. Moreover, the transistor of the semiconductor device 100 in FIG. 1 has the following structure: a certain part of the hetero semiconductor region 3 is etched, to thereby form a CVD oxidized film (thickness about 0.1 μm) as the gate insulating film 4 adjacent to the hetero junction part HJ1 between the hetero semiconductor region 3 and the drift region 2. Moreover, on the gate insulating film 4, there is formed the gate electrode 5 made of N⁺ type polycrystalline silicon.

Each of i) the source electrode 6 of the transistor of the semiconductor device 100 in FIG. 1 and ii) the anode 16 of the diode of the semiconductor device 200 in FIG. 3 includes a metal electrode made of titanium and aluminum. Meanwhile, each of i) the drain electrode 7 of the transistor of the semiconductor device 100 in FIG. 1 and ii) the cathode 17 of the diode of the semiconductor device 200 in FIG. 3 includes a metal electrode made of titanium and nickel.

Then, set forth in detail hereinafter is forward bias characteristics of the diode of the semiconductor device 200 in FIG. 3, in other words, measurement result of current characteristic obtained by grounding the cathode 17 while applying the positive potential to the anode 16. FIG. 4 is a graph showing forward current-voltage characteristics observed when a forward bias is applied to the diode of the semiconductor device 200 in FIG. 3.

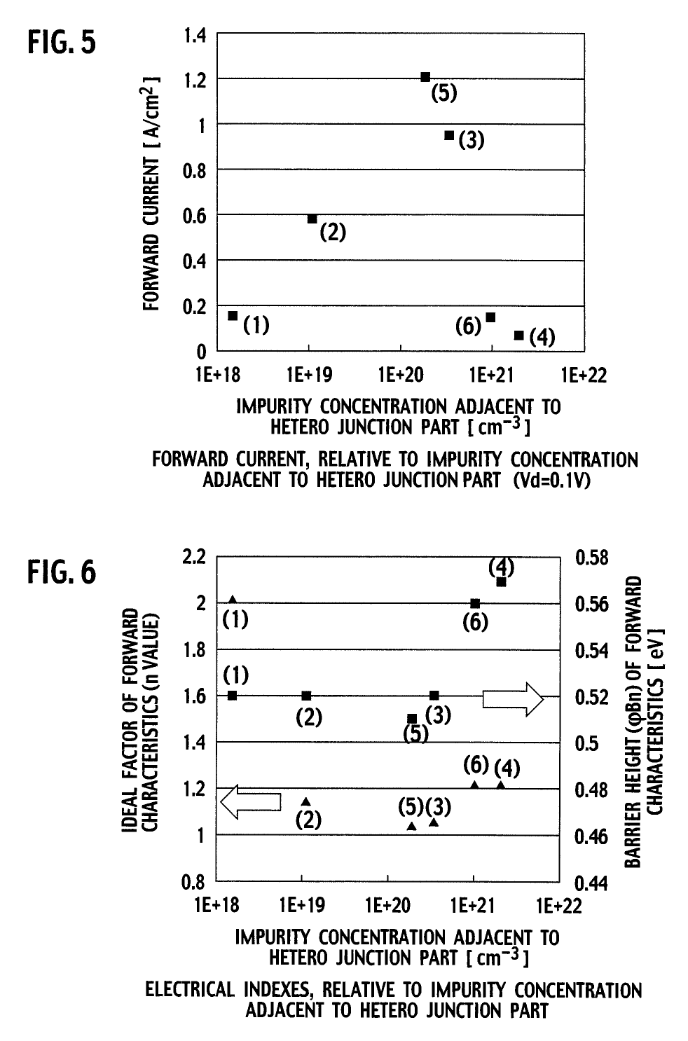

Through the above experiment, as shown in the forward current-voltage characteristics in FIG. 4, a plurality of kinds and introduction methods of the impurity are provided for measuring the impurity concentration in and adjacent to the hetero junction part HJ1 in the hetero semiconductor region 3, thereby setting the following six kinds of experimental conditions. Specifically, the plurality of the experimental conditions include the following in FIG. 4: numerals (1), (2), (3) and (4) denoting arsenic ion implantation, numeral (5) denoting phosphor ion implantation, and numeral (6) denoting deposition of phosphor, oxygen and chlorine (POCl₃). In addition, the concentration of the impurities introduced to the hetero junction part HJ1 in and adjacent to the hetero semiconductor region 3 is observed through the SIMS analysis. As shown in FIG. 5 which is to be described in detail afterward, (1) to (6) are sequentially set as follows respectively:

| | | |
|---|---|---|
| (1) | 1.5 × 10¹⁸ cm⁻³ | arsenic |
| (2) | 1.1 × 10¹⁹ cm⁻³ | arsenic |
| (3) | 3.4 × 10²⁰ cm⁻³ | arsenic |
| (4) | 2.0 × 10²¹ cm⁻³ | arsenic |
| (5) | 1.9 × 10²⁰ cm⁻³ | phosphor |
| (6) | 1.0 × 10²¹ cm⁻³ | phosphor, oxygen and chlorine (POCl₃) |

As shown in FIG. 4, differences in the forward bias current-voltage characteristics can be observed, according to each of the above conditions. For more clarifying the evaluation result of each of the experimental conditions, however, the above differences relative to the concentration of the implanted impurity are to be explained hereinafter.

The diode of the semiconductor device 200 in FIG. 3 according to the first embodiment makes a unipolar operation. Therefore, for electrically evaluating the state of the junction interface of the hetero junction part HJ1, an evaluation using current rising characteristic can be used which evaluation is generally used for evaluating Schottky barrier diode. That is, from a current scale at a certain voltage, a pseudo-evaluation is accomplished for evaluating:

i) height (φBn) of a barrier formed in the hetero junction part HJ1, and
ii) whether or not an ideal barrier is formed.

In view of the above, the following relations 1), 2) and 3) can be obtained:
Relation 1) the scale of the forward current, relative to the impurity concentration observed in and adjacent to the hetero junction part HJ1 through the SIMS analysis (see FIG. 5),
Relation 2) the height (φBn) of the barrier in the hetero junction part HJ1 as the forward characteristic obtained from the scale of the forward current, relative to the impurity concentration observed in and adjacent to the hetero junction part HJ1 through the SIMS analysis (see FIG. 6), and
Relation 3) an ideal factor (n value) of the forward characteristic showing whether or not the ideal barrier is formed, relative to the impurity concentration observed in and adjacent to the hetero junction part HJ1 through the SIMS analysis (see FIG. 6).

FIG. 5 is a graph showing the forward current, relative to the impurity concentration observed in and adjacent to the hetero junction part HJ1 of the diode of the semiconductor device 200 in FIG. 3, specifically, the forward current relative to the impurity concentration, with the anode 16 having a potential Vd of 0.1 V. Moreover, FIG. 6 is a graph showing electrical indexes, relative to the impurity concentration observed in and adjacent to the hetero junction part HJ1 of the diode of the semiconductor device 200 in FIG. 3, specifically, i) the barrier height (φBn) calculated from the forward current-voltage characteristic in FIG. 4 (see right ordinate in FIG. 6) and ii) the ideal factor (n value) (see left ordinate in FIG. 6). In FIG. 6, the square mark ▪ denotes the barrier height (φBn) relative to the impurity concentration, while the triangle mark ▴ denotes the ideal factor (n value) relative to the impurity concentration.

As obvious from the forward current relative to the impurity concentration in FIG. 5, the impurity concentration (in and adjacent to the hetero junction part HJ1) about 10²⁰ cm⁻³ causes the highest forward current, while the impurity concentration about 10²¹ cm⁻³ is likely to rapidly prevent the forward current. The above tendency is equally likely whether the impurity is arsenic or phosphor. In addition, the above tendency does not have so much to do with the method for introducing the impurity. In an ideal state, in general, the higher the impurity concentration of the hetero semiconductor region 13 is, the more the Fermi level is spaced apart from the valence band. Thereby, the Fermi level is likely to be moved to the conduction band side. With this, the current flowing in the hetero junction part HJ1 between the hetero conductor region 13 and the drift region 12 is supposed to get larger. However, the present experimental result, contrary to the above, brings about an effect of preventing the flow of the current at the boundary of about 10²⁰ cm⁻¹.

Moreover, from the electrical indexes relative to the impurity concentration in FIG. 6, specifically, from each of i) the barrier height (φBn) calculated from the electric characteristic wave form relative to the impurity concentration and ii) the ideal factor (n value) relative to the impurity concentration, the same holds true.

At first, concerning the barrier height (φBn):

In the impurity implantation condition (3) showing a low impurity concentration about 3×10²⁰ cm⁻³ (3.4×10²⁰ cm⁻³) or below, the barrier height (φBn) of each of arsenic and phosphor (not shown) is about 0.52 eV. Meanwhile, the impurity implantation conditions (6) and (4) showing over 3×10²⁰ cm⁻³, specifically, about (1 to 2)×10²¹ cm⁻³, have the barrier height (φBn) as large as 0.56 eV.

Then, concerning the ideal factor (n value):

From the impurity implantation conditions (1) to (2), then to (5) and (3 ), in other words, from the low impurity concentration about 10¹⁸ cm⁻³ to about (1 to 3)×10²⁰ cm⁻³, the ideal factor (n value) approaches “1” denoting the ideal state. On the contrary, in the conditions (6) and (4) showing the high impurity concentration over 3×10²⁰ cm⁻³, specifically, about (1 to 2)×10²¹ cm⁻³, however, the ideal factor (n value) is deteriorated to 1.22. Herein, even starting from the impurity concentration of “0” as the low impurity concentration, the forward current is substantially proportional to the impurity concentration until about (1 to 3)×10²⁰ cm⁻³. In other words, until about (1 to 3)×1020 cm⁻³, the higher the impurity concentration is, the larger the forward current is, featuring a tendency that the ideal factor (n value) gradually approaches “1” denoting the ideal state.

As shown in FIG. 5 and FIG. 6, with the structure of the diode of the semiconductor device 200 in FIG. 3 according to the first embodiment, the hetero junction part HJ1 (interface) has a change in the electrical characteristic at the boundary of the impurity concentration about 10²¹ cm⁻³. The impurity concentration in and adjacent to the hetero junction part HJ1 over 10²¹ cm⁻³ suppresses the current flow, influencing the electrical characteristic.

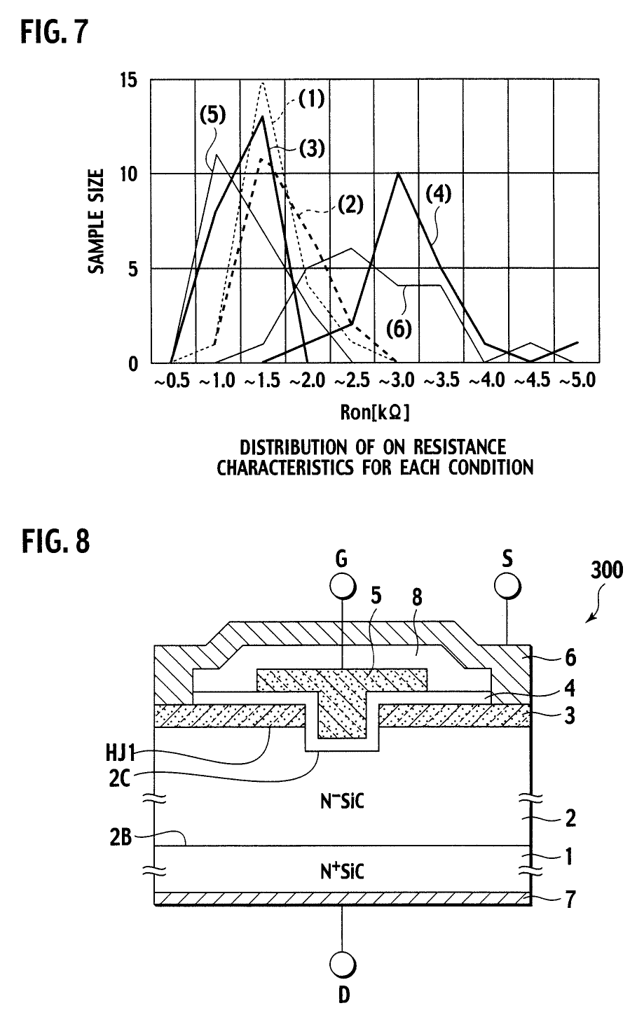

Then, the on resistance of the transistor of the semiconductor device 100 in FIG. 1 is to be set forth. As shown in FIG. 7, samples of the impurity implantation conditions (1), (2), (3) and (5) featuring the impurity concentration less than 10²¹ cm⁻³ show substantially the same on resistance within a range of on resistance variation of about 1.0 kΩ to 2.0 kΩ. Meanwhile, the sample of the impurity implantation condition (6) having the large impurity concentration of 1.0×10²¹ cm⁻³ shows the on resistance about 2 to 3 times larger than that of the impurity implantation conditions (1), (2), (3) and (5), bringing about deteriorated result. Moreover, the sample of the impurity implantation condition (4) having a still larger impurity concentration about 2.0×10²¹ cm⁻³ shows the on resistance about 3 to 4 times larger than that of the impurity implantation conditions (1), (2), (3) and (5), bringing about a further deteriorated result. Herein, FIG. 7 is a graph showing characteristic distribution of on resistance concerning the transistor of the semiconductor device 100, with the introduced impurity concentration as a parameter.

Meanwhile, measuring a sheet resistance (that is, a resistance caused when the current flows in parallel to the hetero junction part HJ1) of each of the hetero semiconductor region 3 of the semiconductor device 100 in FIG. 1 and the hetero semiconductor region 13 of the semiconductor device 200 in FIG. 3, it was found that the higher the impurity concentration is the lower the sheet resistance is.

From the above experimental results, the impurity concentration influences the electrical characteristics of the transistor and the diode respectively i) in and adjacent to the hetero junction part HJ1 (interface) between the drift region 2 and the hetero semiconductor region 3 of the semiconductor device 100 in FIG. 1, and ii) in and adjacent to the junction interface HJ1 (interface) between the drift region 12 and the hetero semiconductor region 13 of the semiconductor device 200 in FIG. 3. Moreover, when the impurity concentration in and adjacent to the hetero junction part HJ1 (interface) is more than about 10²¹ cm⁻³, the hetero junction part HJ1 (interface) is so configured as to increase the on resistance.

Therefore, for obtaining the low on resistance when the polycrystalline silicon is used for the hetero semiconductor region 3 (or the hetero semiconductor region 13), it has been found that, preferably, the impurity concentration in and adjacent to the hetero junction part HJ1 (interface) between the hetero semiconductor region 3 (or the hetero semiconductor region 13) and the drift region 2 (or the drift region 12) is so controlled as to be less than or equal to 1E21 cm⁻³=1×10²¹ cm⁻³. In the transistor such as the semiconductor device 100 in FIG. 1, the gate electrode 5 controls thickness of the energy barrier in the hetero junction part HJ1 between the hetero semiconductor region 3 and the drift region 2. With the above transistor, especially, it is preferable to control the gate electrode 5 such that the impurity concentration in the first certain region including at least the certain part contacting the gate insulating film 4 (the certain part is in the certain position that is most adjacent to the hetero junction part HJ1) is less than or equal to 10²¹ cm⁻³.

Scientific causes for deteriorating the electrical characteristic in a condition of the impurity concentration over about 10²¹ cm⁻³ have not been solved sufficiently. It is known generally, however, introducing impurity excessively into the semiconductor to such an extent as to go over a solid solution limit increases resistance. In the case of the hetero junction part HJ1 (interface) as well, the following can be estimated:

Introducing the impurity (having concentration over 10²¹ cm⁻³) into the polycrystalline silicon in the hetero semiconductor region 3 excessively dopes the impurity over the solid solution limit in the semiconductor material, that is, the polycrystalline silicon, and the thus doped impurity may be segregated, thereby causing a screening effect and the like of the electric field.

As set forth above, with the current-voltage characteristic observed when the forward bias is applied to adjacent to the hetero junction part HJ1 of the hetero semiconductor region 3, making the following first concentration smaller than the following second concentration can lower the on resistance during conduction of the semiconductor device 100 or semiconductor device 200:
First concentration): the concentration of the impurity introduced in and adjacent to the hetero junction part HJ1 of the hetero semiconductor region 3 or hetero semiconductor region 13.
Second concentration): a threshold impurity concentration causing a deformation of the current characteristic relative to the impurity concentration in and adjacent to the hetero junction part HJ1 of the hetero semiconductor region 3 or hetero semiconductor region 13.

That is, with the current-voltage characteristic observed when the forward bias is applied to the hetero junction part HJ1, making the following first concentration smaller than the following second concentration can lower the on resistance during the conduction:
First concentration): a) the concentration of the impurity introduced in and adjacent to the hetero junction part HJ1 between i) the hetero semiconductor region 3 (or the hetero semiconductor region 13) and ii) the drift region 2 (or the drift region 12) in the semiconductor base 10 (or the semiconductor base 30),
   especially, in the case of the transistor,
   b) the concentration of the impurity introduced in and adjacent to the certain part of the hetero junction part HJ1 in the hetero semiconductor region 3, the certain part contacting the gate insulating film 4.
Second concentration): a) the threshold impurity concentration disenabling the proportion between the forward current and the impurity concentration.

In other words, controlling the first concentration less than or equal to the solid solution limit of the semiconductor material included in the hetero semiconductor region 3 (or the hetero semiconductor region 13) can lower the on resistance during the conduction.

Moreover, making a structure of the impurity concentration in and adjacent to the hetero junction part HJ1 (interface) by implementing the following first operation and second operation can lower the resistance in the hetero junction part HJ1 (interface) and decrease the sheet resistance in the hetero semiconductor region 3 (or the hetero semiconductor region 13), to thereby further lower the on resistance:
First operation): Making the impurity concentration in and adjacent to the hetero junction part HJ1 (interface) smaller than the impurity concentration causing the solid solution limit to the semiconductor material included in the hetero semiconductor region 3 (or the hetero semiconductor region 13) {that is, the solid solution limit is 10²¹ cm⁻³ when the drift region 2 (or the drift region 12) of the semiconductor base 10 (or the semiconductor base 30) is made of silicon carbide and the hetero semiconductor region 3 (or the hetero semiconductor region 13) is made of polycrystauline silicon}.
Second operation): Allowing the impurity concentration in and adjacent to the hetero junction part HJ1 (interface) to have a distribution substantially equal to the impurity concentration of a second certain region including at least a part of a certain part along or adjacent to the hetero junction part HJ1 between the drift region 2 (or the drift region 12) and the hetero semiconductor region 3 (or the hetero semiconductor region 13).

### Other Embodiments

According to the first embodiment in FIG. 1, as an example, the transistor has been set forth having the basic structure, that is, the semiconductor device 100. Provided that the condition for the impurity concentration in and adjacent to the hetero junction part should be met under the present invention, however, any other added or modified structures can bring about a like effect.

Hereinafter, semiconductor devices having structures different from that of the semiconductor device 100 in FIG. 1 according to the first embodiment are to be set forth, referring to FIG. 8 to FIG. 13.

### Second Embodiment

FIG. 8 is a cross sectional view of a semiconductor device 300, according to a second embodiment of the present invention. Like FIG. 1 according to the first embodiment, FIG. 8 shows an example of a hetero junction transistor. In the semiconductor device 100 in FIG. 1, the surface layer part of the drift region 2 is free from a dug-in recess, and the gate electrode 5 is disposed adjacent to the hetero junction part HJ1 between the hetero semiconductor region 3 and the drift region 2 via the gate insulating film 4. Contrary to the above, with the semiconductor device 300 in FIG. 8, a recess 2C is dug in the surface layer part of the drift region 2, and the gate electrode 5 is embedded in the recess 2C of the drift region 2 via the gate insulating film 4, to thereby form what is called a trench type structure. The semiconductor device 300 having the above structure according to the second embodiment in FIG. 8 can bring about an effect like that according to the first embodiment in FIG. 1.

### Third Embodiment and Fourth Embodiment

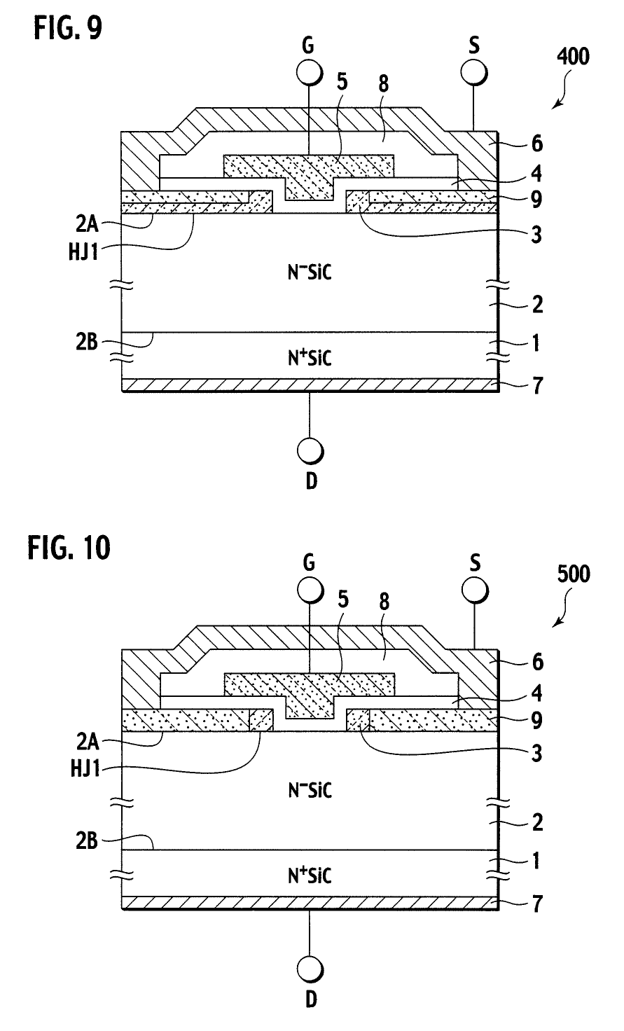

Then, FIG. 9 is a cross sectional view of a semiconductor device 400 according to a third embodiment of the present invention, and FIG. 10 is a cross sectional view of a semiconductor device 500 according to a fourth embodiment of the present invention, like FIG. 1, each showing an example of a hetero junction transistor. The semiconductor device 100 in FIG. 1 includes the N type hetero semiconductor region 3 having the hetero junction part HJ1 in combination with the drift region 2. Meanwhile, the semiconductor device 400 in FIG. 9 and the semiconductor device 500 in FIG. 10 each have a second hetero semiconductor region 9 other than the hetero semiconductor region 3.

Herein, the semiconductor device 400 in FIG. 9 has the second hetero semiconductor region 9 formed in the surface layer part on the periphery of the hetero semiconductor region 3, while the semiconductor device 500 in FIG. 10 has the second hetero semiconductor region 9 formed in an entire area (namely, not only the surface layer part but including a region contacting the drift region 2) on the periphery of the hetero semiconductor region 3 in FIG. 1. Herein, the conduction type and impurity concentration of the second hetero semiconductor region 9 can be arbitrarily set according to application. As a matter of course, not limited to the two kinds of hetero semiconductor regions (i.e., the hetero semiconductor region 3 and the second hetero semiconductor region 9), the semiconductor device 400 in FIG. 9 and the semiconductor device 500 in FIG. 10 each are allowed to have three or more kinds of hetero semiconductor regions. Each of the semiconductor device 400 and the semiconductor device 500 having the above structures according to the respective third embodiment and fourth embodiment in FIG. 9 and FIG. 10 can bring about an effect like that according to the first embodiment in FIG. 1.

### Fifth Embodiment and Sixth Embodiment

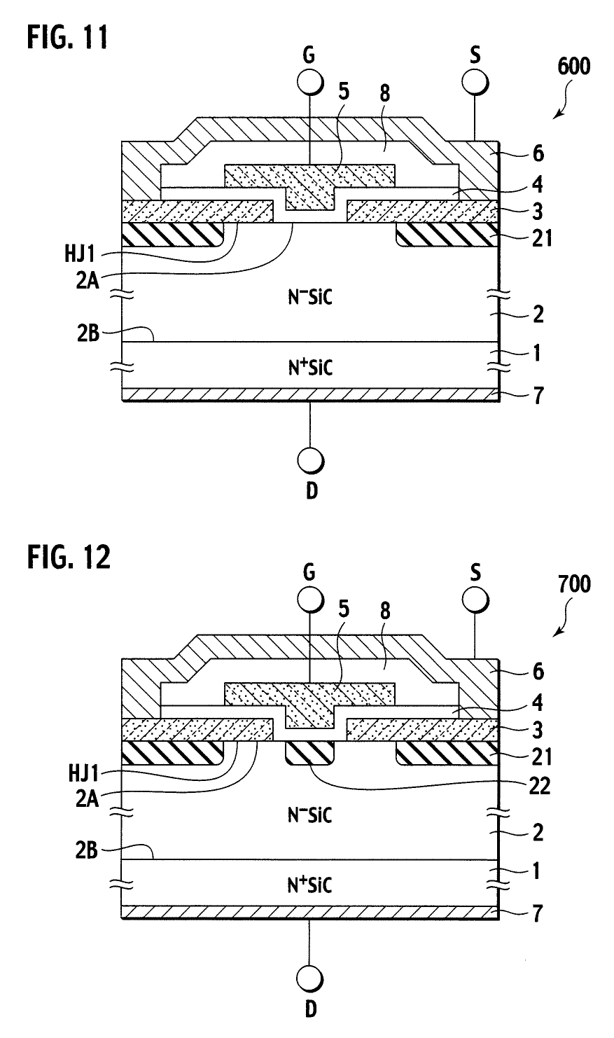

Moreover, FIG. 11 is a cross sectional view of a semiconductor device 600 according to a fifth embodiment of the present invention, and FIG. 12 is a cross sectional view of a semiconductor device 700 according to a sixth embodiment of the present invention, like FIG. 1, each showing an example of a hetero junction transistor. The drift region 2 of the semiconductor device 100 in FIG. 1 is free from a region for relaxing the electric field of the hetero junction part HJ1 (interface). Meanwhile, the drift region 2 of the semiconductor device 600 in FIG. 11 includes a first electric field relaxation region 21, while the drift region 2 of the semiconductor device 700 in FIG. 12 has both of the first electric field relaxation region 21 and a second electric field relaxation region 22.

The semiconductor device 600 in FIG. 11 has the first electric field relaxation region 21 formed in the surface layer part of the peripheral part of the drift region 2. Meanwhile, the semiconductor device 700 in FIG. 12 has the first electric field relaxation region 21 formed in the surface layer part of the peripheral part of the drift region 2 and the second electric field relaxation region 22 formed in the surface layer part of the center part of the drift region. Forming the first electric field relaxation region 21 can, in the shutoff state, relax the electric field applied to the hetero junction part HJ1 (interface) between the hetero semiconductor region 3 and the drift region 2, thus decreasing leak current, to thereby further improve shutoff performance, which is an effect in addition to the effect according to the first embodiment. Moreover, the semiconductor device 700 in FIG. 12 having the second electric field relaxation region 22 can relax the electric field applied to the gate insulating film 4, thus preventing insulation breakage which may be caused to the gate insulating film 4, to thereby improve reliability, which is also an effect in addition to the effect according to the first embodiment.

The first electric field relaxation region 21 and the second electric field relaxation region 22 each may include any of P type region, high resistance region and insulation region. Moreover, though the second electric field relaxation region 22 is formed in combination with the first electric field relaxation region 21 in FIG. 12 according to the sixth embodiment, the second electric field relaxation region 22 alone can be formed.

### Seventh Embodiment

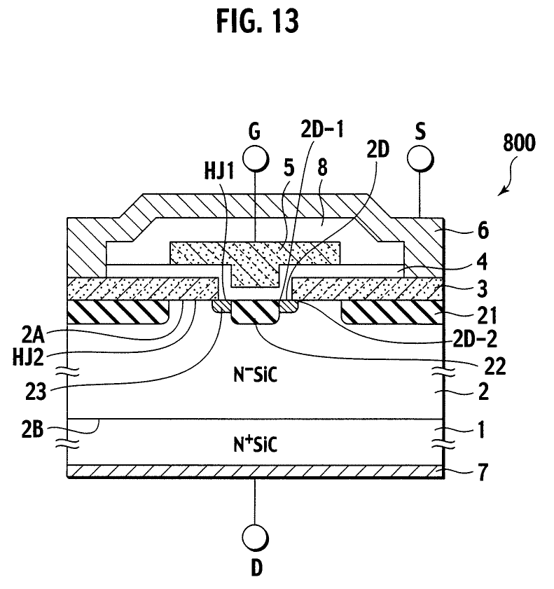

Moreover, FIG. 13 is a cross sectional view of a semiconductor device 800 according to a seventh embodiment of the present invention, like FIG. 1, showing an example of a hetero junction transistor. The semiconductor device 800 in FIG. 13 has an N⁺ type conduction region 23 having an impurity concentration higher than that of the drift region 2. The N⁺ type conduction region 23 is formed in the drift region 2's certain region 2D with which each of the gate insulating film 4 and the hetero semiconductor region 3 has a contact. Specifically, the certain region 2D is defined from a region 2D-1 adjacent to the second electric field relaxation region 22 formed in the surface layer part of the drift region 2 to a region 2D-2 up to the hetero semiconductor region 3 along the surface layer part.

In addition, in the semiconductor device 800 in FIG. 13, the N⁺ type conduction region 23 is formed in combination with the second electric field relaxation region 22 and the first electric field relaxation region 21. Otherwise, forming of the N⁺ type conduction region 23 alone or in combination with any one of the second electric field relaxation region 22 and the first electric field relaxation region 21 is allowed.

Forming the semiconductor device 800 having the above structure in FIG. 13 can, in the conduction state, relax the energy barrier of a hetero junction part HJ2 between the hetero semiconductor region 3 and the N⁺ type conduction region 23, to thereby bring about higher conduction characteristic, which is an effect in addition to the effect according to the first embodiment. In other words, the on resistance can be made further smaller, thus improving the conduction performance.

As set forth above, the present invention has been described in detail by citing various semiconductor devices 300, 400, 500, 600, 700, 900 applied to the transistor structures, according to the respective second embodiment to seventh embodiment, the devices 300, 400, 500, 600, 700, 800 each different in structure from the semiconductor device 100 according to the first embodiment. As a matter of course, the effect of the present invention can be brought about by diodes having structures like that according to the respective second embodiment to seventh embodiment and therefore different from the structure of the diode of the semiconductor device 200 in FIG. 3. Namely, like the semiconductor device 200 in FIG. 3 and as shown in the graphs in FIG. 4 to FIG. 6, so controlling the impurity concentration as to be less than or equal to the solid solution limit of the hetero semiconductor region 13 in and adjacent to the hetero junction part HJ1 in the hetero semiconductor region 13 can decrease the on resistance, even in the case of diode, thereby obtaining high current value.

Although the present invention has been described above by reference to certain embodiments, the present invention is not limited to the embodiments described above. Modifications and variations of the embodiments described above will occur to those skilled in the art, in light of the above teachings.

Specifically, according to the first embodiment to seventh embodiment, the semiconductor devices 100 (200), 300, 400, 500, 600, 700 and 800 each have the silicon carbide as the material for the semiconductor bases 10 (30). The effect of the semiconductor device under the present invention is determined by the impurity concentration of any of i) the hetero semiconductor region 3 of the semiconductor device 100 (the transistor) in FIG. 1 and ii) the hetero semiconductor region 13 of the semiconductor device 200 (diode). Therefore, the semiconductor bases 10, 30 may be made of other semiconductor materials such as gallium nitride, diamond and the like.

Moreover, according to the first embodiment to seventh embodiment, 4H type is used as poly type of the silicon carbide. Other poly types such as 6H (6-layer hexagonal crystal), 3C (3-layer cubic crystal) and the like are allowed.

Moreover, according to the first embodiment to seventh embodiment, the drain electrode 7 (or cathode 17) and the source electrode 6 (or anode 16) are so configured as to oppose each other sandwiching therebetween the drift region 2 (or drift region 12) and the current is caused to flow in the longitudinal direction, to thereby form a structure what is called a longitudinal transistor or diode. Otherwise, for example, the drain electrode 7 (or cathode 17) and the source electrode 6 (or anode 16) may be disposed on one main face, with the current flowing in the lateral direction, to thereby form a structure what is called a lateral transistor or diode.

Moreover, the polycrystalline silicon is used for the hetero semiconductor region 3 (or hetero semiconductor region 13). However, other materials forming the hetero junction part (HJ1, HJ2) in combination with the silicon carbide are allowed, examples thereof including:
1) other silicon materials such as single crystal silicon, amorphous silicon and the like,
2) other semiconductor materials such as germanium, silicon germanium, gallium arsenide and the like, and
3) other poly types of silicon carbide such as 6H, 3C and the like.

In view of the causes for the characteristics of the present invention, it has been found out that the characteristics of the present invention are not brought about by an inherent phenomenon of the semiconductor material, but can be brought about by any materials. Controlling the concentration of the introduced impurity less than or equal to the solid solution limit of the semiconductor material included in the hetero semiconductor region can bring about the effect described above.

Moreover, according to the above embodiments, the N type silicon carbide as the drift region 2 (or drift region 12) and the N type polycrystalline silicon as the hetero semiconductor region 3 (or hetero semiconductor region 13) are combined. Otherwise, combining the N type silicon carbide with a P type polycrystalline silicon, combining a P type silicon carbide with the P type polycrystalline silicon, combining the P type silicon carbide with the N type polycrystalline silicon are allowed.

Not to mention, however, the above modifications should not be deviated from the subject (scope) of the present invention.

This application is based on a prior Japanese Patent Application No. P2006-125399 (filed on Apr. 28, 2006 in Japan). The entire contents of the Japanese Patent Application No. P2006-125399 from which priority is claimed are incorporated herein by reference, in order to take some protection against translation errors or omitted portions.

The scope of the present invention is defined with reference to the following claims.

What is claimed is:

1. A semiconductor device, comprising:
1) a semiconductor base having a first face;
2) a hetero semiconductor region configured to contact the first face of the semiconductor base and different from the semiconductor base in band gap, the semiconductor base and the hetero semiconductor region defining therebetween a junction part in the hetero semiconductor region, a concentration of an impurity introduced in at least a first certain region including the junction part being less than or equal to a solid solution limit to a semiconductor material included in the hetero semiconductor region;
3) a first electrode configured to be connected to the hetero semiconductor region; and
4) a second electrode configured to be connected to the semiconductor base.

2. The semiconductor device according to claim 1, wherein the first electrode is an anode while the second electrode is a cathode.

3. The semiconductor device according to claim 1, wherein, in a current-voltage characteristic observed when a forward bias is applied to at least the junction part,
the concentration of the impurity introduced in the at least the first certain region including the junction part is smaller than a threshold impurity concentration which disables a proportion between the current of the current-voltage characteristic and the concentration of the impurity.

4. The semiconductor device according to claim 1, wherein
the concentration of the impurity introduced in the at least the first certain region including the junction part is so distributed as to be substantially equal to an impurity concentration in a second certain region including at least a part of a certain part along or adjacent to the junction part.

5. The semiconductor device according to claim 1, wherein the semiconductor base is made of a material selected from the group consisting of silicon carbide, gallium nitride and diamond.

6. The semiconductor device according to claim 1, wherein the hetero semiconductor region is made of a material selected from the group consisting of single crystal silicon, polycrystalline silicon, amorphous silicon, germanium, silicon germanium and gallium arsenide.

7. The semiconductor device according to claim 6, wherein
when the hetero semiconductor region is made of the polycrystalline silicon, the concentration of the impurity introduced in the at least the first certain region including the junction part is less than or equal to 1E21 cm⁻³.

8. The semiconductor device according to claim 1, wherein the semiconductor device is a diode.

9. A semiconductor device, comprising:
1) a semiconductor base having a first face;
2) a hetero semiconductor region configured to contact the first face of the semiconductor base and different from the semiconductor base in band gap, the semiconductor base and the hetero semiconductor region defining therebetween a junction part in the hetero semiconductor region, a concentration of an impurity introduced in at least a first certain region including the junction part being less than or equal to a solid solution limit to a semiconductor material included in the hetero semiconductor region;
3) a gate electrode formed, via a gate insulation film, in a certain position adjacent to the junction part;
4) a source electrode configured to be connected to the hetero semiconductor region; and
5) a drain electrode configured to be connected to the semiconductor base.

10. The semiconductor device according to claim 9, wherein the at least the first certain region including the junction part includes a certain part contacting the gate insulation film.

11. The semiconductor device according to claim 9, wherein, in a current-voltage characteristic observed when a forward bias is applied to at least the junction part,
the concentration of the impurity introduced in the at least the first certain region including the junction part is smaller than a threshold impurity concentration which disables a proportion between the current of the current-voltage characteristic and the concentration of the impurity.

12. The semiconductor device according to claim 9, wherein
the concentration of the impurity introduced in the at least the first certain region including the junction part is so distributed as to be substantially equal to an impurity concentration in a second certain region including at least a part of a certain part along or adjacent to the junction part.

13. The semiconductor device according to claim 9, wherein the semiconductor base is made of a material selected from the group consisting of silicon carbide, gallium nitride and diamond.

14. The semiconductor device according to claim 9, wherein the hetero semiconductor region is made of a material selected from the group consisting of single crystal silicon, polycrystalline silicon, amorphous silicon, germanium, silicon germanium and gallium arsenide.

15. The semiconductor device according to claim 14, wherein
when the hetero semiconductor region is made of the polycrystalline silicon, the concentration of the impurity introduced in the at least the first certain region including the junction part is less than or equal to 1E21 cm⁻³.

16. The semiconductor device according to claim 9, wherein
the semiconductor device includes a second hetero semiconductor region formed in any one of the following:
1) in a surface layer part on a periphery of the hetero semiconductor region, and
2) in an entire area on the periphery of the hetero semiconductor region.

17. The semiconductor device according to claim 9, wherein the semiconductor device is configured to include at least one of the following:
1) a first electric field relaxation region formed in a surface layer part of a peripheral part of a drift region of the semiconductor base, the drift region defining the junction part in combination with the hetero semiconductor region, and
2) a second electric field relaxation region formed in a surface layer part of a center part of the drift region.

18. The semiconductor device according to claim 17, wherein
the semiconductor device has a conduction region having an impurity concentration higher than that of the drift region, and
the conduction region is formed in a certain region of the drift region, the gate insulating film and the hetero semiconductor region having a contact with the certain region of the drift region.

19. The semiconductor device according to claim 18, wherein
the certain region of the drift region is defined from a first region adjacent to the second electric field relaxation region formed in the surface layer part of the drift region to a second region up to the hetero semiconductor region along the surface layer part of the drift region.

20. The semiconductor device according to claim 9, wherein the semiconductor device is a transistor.
